(19) United States
(12) Patent Application Publication
(10) Pub. No.: US 2025/0075124 A1
(43) Pub. Date: Mar. 6, 2025

(54) LIGHT-EMITTING ELEMENT, INK COMPOSITION AND DISPLAY DEVICE INCLUDING THE LIGHT-EMITTING ELEMENT

(71) Applicant: Samsung Display Co., Ltd., Yongin-si (KR)

(72) Inventors: Jungho JO, Yongin-si (KR); SANGYEOP LEE, Yongin-si (KR); SOOHO LEE, Yongin-si (KR); YUNKU JUNG, Yongin-si (KR); Chang Yeol HAN, Yongin-si (KR)

(21) Appl. No.: 18/796,960

(22) Filed: Aug. 7, 2024

(30) Foreign Application Priority Data
Sep. 6, 2023 (KR) 10-2023-0118404

(51) Int. Cl. C09K 11/66; B82Y 30/00; C09D 11/38; C09K 11/02; H10K 50/115; H10K 50/16; H10K 50/17; H10K 102/00

(52) U.S. Cl. CPC C09K 11/661; B82Y 30/00; C09D 11/38; C09K 11/02; H10K 50/115; H10K 50/16; H10K 50/171; C09K 2211/10; H10K 2102/331

(57) ABSTRACT

A light-emitting element includes a first electrode, a functional layer disposed on the first electrode, and a second electrode disposed on the functional layer, wherein the functional layer includes a nanoparticle, the nanoparticle includes a core and a ligand, the core includes at least one of a first core compound represented by Formula 1 below, a second core compound represented by Formula 2 below, or a third core compound represented by Formula 3 below, and thus the light-emitting element has improved lifespan and efficiency.

Sn⁴⁺₁₋ₓSn²⁺ₓO₂₋ₓ Formula 1

Sn⁴⁺_{1-y}Cu⁺_{2y}O_{2-y} Formula 2

Sn⁴⁺_{1-z}Ni²⁺_{z}O_{2-z} Formula 3

### CROSS-REFERENCE TO RELATED APPLICATION

The present application claims priority to and the benefit of Korean Patent Application No. 10-2023-0118404, filed on Sep. 6, 2023, the entire content of which is incorporated herein by reference.

### BACKGROUND

### 1. Field

The present disclosure herein relates to a light-emitting element, an ink composition, and a display device including the light-emitting element, and for example, to a light-emitting element having improved luminous efficiency and element lifespan and a display device including the same.

### 2. Description of the Related Art

Recently, organic electroluminescence display devices have been actively developed as image display devices. Organic electroluminescence display devices, different from liquid crystal display devices, are so-called self-luminous type or kind display devices that recombine, in an emission layer, holes and electrons respectively injected from a first electrode and a second electrode, thereby causing a light-emitting material of the emission layer to emit light to implement displays (e.g., to display an image).

For application of organic electroluminescence elements to display devices, there is a demand or desire for organic electroluminescence elements having a relatively high luminous efficiency, and a relatively long life (lifespan), and the development of materials capable of stably attaining such characteristics for light-emitting elements is being continuously pursued or required.

For example, to achieve a light-emitting element having a relatively high efficiency and a relatively long lifespan, materials having excellent or suitable electron mobility and stability for an electron transport region are under development or pursued.

### SUMMARY

Aspects according to embodiments of the present disclosure are directed toward a light-emitting element having improved luminous efficiency and element lifespan.

Aspects according to embodiments of the present disclosure are directed toward an ink composition capable of improving emission characteristics and element lifespan of a light-emitting element.

Aspects according to embodiments of the present disclosure are directed toward a display device including the light-emitting element having improved luminous efficiency and element lifespan. Additional aspects will be set forth in part in the description which follows and, in part, will be apparent from the description, or may be learned by practice of the presented embodiments of the disclosure.

According to an embodiment of the present disclosure, a light-emitting element includes a first electrode, a functional layer on the first electrode, and a second electrode on the functional layer, wherein the functional layer includes a nanoparticle, the nanoparticle includes a core and a ligand, and the core includes at least one of a first core compound represented by Formula 1, a second core compound represented by Formula 2, or a third core compound represented by Formula 3.

Sn⁴⁺₁₋ₓSn²⁺ₓO₂₋ₓ, Formula 1
where in Formula 1 above,
x is more than about 0, and about 0.3 or less (e.g., x is greater than 0 and less than or equal to about 0.3),

Sn⁴⁺_{1-y}Cu⁺_{2y}O_{2-y}, Formula 2
where in Formula 2 above,
y is more than 0, and 0.3 or less (e.g., y is greater than 0 and less than or equal to about 0.3),

Sn⁴⁺_{1-z}Ni²⁺_{z}O_{2-z}, Formula 3
where in Formula 3 above,
z is more than 0, and 0.3 or less (e.g., z is greater than 0 and less than or equal to about 0.3).

In one or more embodiments, the nanoparticle may be composed of the core and the ligand, and the core may be composed of the first core compound.

In one or more embodiments, the nanoparticle may have a peak intensity ratio of Sn²⁺ 3d_{5/2} with respect to Sn⁴⁺ 3d_{5/2} of greater than about 0, and about 0.6 or less (e.g., greater than 0 and less than or equal to about 0.6), measured utilizing X-ray photoelectron spectroscopy (XPS).

In one or more embodiments, the nanoparticle may have an absolute quantum yield of greater than about 0%, and about 5% or less (e.g., greater than 0% and less than or equal to about 5%).

In one or more embodiments, the nanoparticle may be composed of e.g., consist essentially of or consists of or include only) the core and the ligand, and the core may be composed of (e.g., consist essentially of or consists of or include only) at least one of the first core compound, the second core compound, or the third core compound.

In one or more embodiments, the ligand may include an oleic acid or oleylamine.

In one or more embodiments, the ligand may be chemically bonded to the core.

In one or more embodiments, the nanoparticle may be doped with a metal atom.

In one or more embodiments, the metal atom may include at least one of Zn, Mg, Li, or Na.

In one or more embodiments, the functional layer may include a hole transport region on the first electrode, an emission layer on the hole transport region, and an electron transport region between the emission layer and the second electrode, wherein the electron transport region may include the nanoparticle.

In one or more embodiments, the electron transport region may include an electron transport layer on the emission layer, and an electron injection layer on the electron transport layer, and at least one of the electron transport layer or the electron injection layer may include the nanoparticle.

In one or more embodiments, the emission layer may include a quantum dot.

In one or more embodiments of the present disclosure, an ink composition includes a nanoparticle, and a solvent, wherein the nanoparticle includes a core and a ligand, and the core includes at least one of a first core compound represented by Formula 1, a second core compound represented by Formula 2, or a third core compound represented by Formula 3.

In one or more embodiments, the solvent may be hydrophobic.

In one or more embodiments, the nanoparticle may include the core and the ligand, and the core may include the first core compound.

In one or more embodiments, the nanoparticle may include the core and the ligand, and the core may include the second core compound or the third core compound.

In one or more embodiments of the present disclosure, a display device includes a base layer, a circuit layer on the base layer, and a display element layer on the circuit layer and including the light-emitting element, wherein the light-emitting element includes a first electrode, a second electrode on the first electrode, and an electron transport region between the first electrode and the second electrode and including a nanoparticle, the nanoparticle includes a core and a ligand, the core includes at least one of a first compound represented by Formula 1, a second core compound represented by Formula 2, and a third core compound represented by Formula 3.

In one or more embodiments, the light-emitting element may further include a hole transport region on the first electrode and an emission layer between the hole transport region and the electron transport region.

In one or more embodiments, the emission layer may include a quantum dot.

In one or more embodiments, the electron transport region may include an electron transport layer on the emission layer, and an electron injection layer on the electron transport layer, and at least one of the electron transport layer or the electron injection layer may include the nanoparticle.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a perspective view illustrating a display device according to one or more embodiments;

FIG. 2 is a cross-sectional view illustrating a portion taken along the line I-I′ in FIG. 1;

FIG. 3 is a plan view illustrating a display device according to one or more embodiments;

FIG. 4 is a cross-sectional view illustrating a portion taken along the line II-II′ in FIG. 3;

FIG. 5 is a cross-sectional view illustrating a light-emitting element according to one or more embodiments; and

FIG. 6 illustrates a portion of an ink composition according to one or more embodiments.

### DETAILED DESCRIPTION

The present disclosure may have one or more suitable modifications and may be embodied in different forms, and example embodiments will be explained in more detail with reference to the accompanying drawings. However, the present disclosure should not be construed as limited to one or more embodiments set forth herein, and should be understood to include all suitable modifications, equivalents, and substituents which are included in the spirit and technical scope of the present disclosure.

As used herein, if (e.g., when) a component (or a region, a layer, a part, and/or the like) is referred to as being “on”, “connected to”, or “bonded to” other components, it can be “directly arranged on/connected to/bonded to” the other component, or a third intervening component may also be present therebetween.

Like reference numerals and symbols refer to like elements throughout, and duplicative descriptions thereof may not be provided. In the drawings, the thicknesses, ratios, and dimensions of components are exaggerated for effective descriptions of technical contents. A term “and/or” may include any and all combinations of one or more of the associated listed items.

Terms such as first and second may be used to describe various components, but the components should not be limited by the terms. These terms are only used for the purpose of distinguishing one component from other components. For example, without departing from the scope of the present disclosure, a first component may be referred to as a second component, and similarly, a second component may be referred to as a first component. Singular expressions include plural expressions unless the context clearly indicates otherwise.

In addition, terms such as “below”, “lower”, “above”, and “upper” are used to describe the relationship between components shown in the drawings. The terms are relative concepts and are described based on the directions indicated in the drawings.

Terms such as “include” or “have” are intended to designate the presence of a feature, number, (e.g., act or task) step, action, component, part, or combination thereof described in the specification, and it should be understood that it does not preclude the possibility of presence or addition of one or more other features, numbers, steps, operations, components, parts, and/or combination thereof.

Unless otherwise defined, all terms (including technical and scientific terms) used in this specification have the same meaning as commonly understood by one of ordinary skill in the art to which this disclosure belongs. In addition, terms such as terms defined in commonly used dictionaries should be interpreted as having a meaning consistent with the meaning in the context of the related technology, and should not be interpreted as too ideal or too formal unless explicitly defined here.

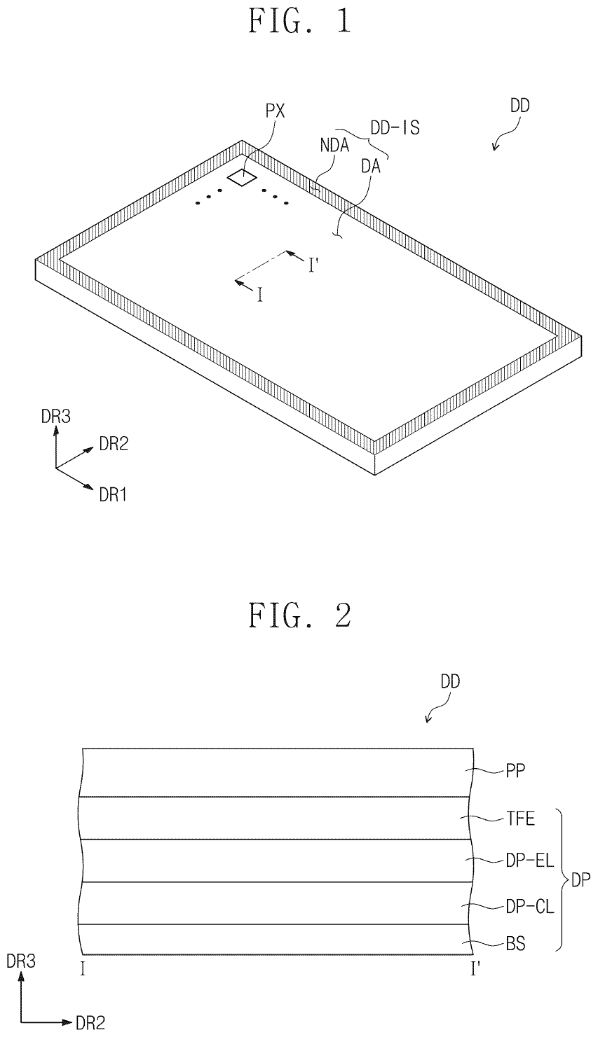

Hereinafter, with reference to drawings, a light-emitting element according to one or more embodiments of the present disclosure and a display device including the light-emitting element will be described in more detail. FIG. 1 is a perspective view illustrating a display device according to one or more embodiments.

Referring to FIG. 1, a display device DD according to one or more embodiments may be activated in response to an electrical signal. For example, the display device DD may be a large-sized device such as a television, a monitor, and/or an outdoor billboard. In one or more embodiments, the display device DD may be a medium or small-sized device such as a personal computer, a laptop computer, a personal digital terminal, a car navigation unit, a game console, a smartphone, a tablet, and/or a camera. However, these devices are suggested as examples, other electric devices may be utilized as long as without departing from the subject matter of the present disclosure.

The display device DD may display an image (or a video image) through a display surface DD-IS. The display surface DD-IS may be parallel (e.g., include parallel sides) with a plane defined by a first direction DR1 and a second direction DR2. The display surface DD-IS may include a display region DA and a non-display region NDA.

In the display region DA, a pixel PX may be arranged and in the non-display region NDA, a pixel may not be arranged. The non-display region NDA may be defined along an edge of the display surface DD-IS. The non-display region NDA may be around (e.g., surround) the display region DA. However, embodiments of the present disclosure are not limited thereto, for example, the non-display region NDA may not be provided, or the non-display region NDA may be arranged on only one side of the display region DA.

FIG. 1 illustrates the display device DD as having a flat display surface DD-IS, but one or more embodiments of the present disclosure is not limited thereto. The display device DD may include a curved display surface or a three-dimensional display surface. The three-dimensional display surface may include a plurality of display regions, each indicating (e.g., oriented towards) different directions.

FIG. 1 and other drawings illustrate a first directional axis DR1 to a third directional axis DR3, directions indicated by the first to third directional axes DR1, DR2, and DR3, described herein, are relative concepts, and may be changed to other suitable directions. In one or more embodiments, the directions indicated by the first to third directional axes DR1, DR2, and DR3 may be described as first to third directions, and the same reference numerals and symbols may be utilized. As used herein, the first directional axis DR1 and the second directional axis DR2 are normal (e.g., perpendicular) to each other, and the third directional axis DR3 is a normal direction with respect to the plane defined by the first directional axis DR1 and the second directional axis DR2. As used herein, a “plane” refers to the plane defined by the first directional axis DR1 and the second directional axis DR2, and a “cross-section” refers to a surface that is orthogonal to the plane defined by the first directional axis DR1 and the second directional axis DR2, and is parallel to the third directional axis DR3. A thickness direction of the display device DD may be parallel to the third direction DR3, which is a normal direction with respect to the plane defined by the first direction DR1 and the second direction DR2.

As used herein, a top surface (or a front surface) and a bottom surface (or a rear surface) of members forming the display device DD may be defined with respect to the third direction DR3. For example, among two surfaces facing each other with respect to the third direction DR3 in one member, a surface relatively adjacent to the display surface DD-IS may be defined as a front surface (or a top surface) and a surface relatively spaced and/or apart (e.g., spaced apart or separated) from the display surface DD-IS may be defined as a rear surface (or a bottom surface). In addition, as used herein, an upper part (or an upper side) and a lower part (or a lower side) may be defined with respect to the third direction DR3, the upper part (or the upper side) may be defined in a direction towards the display surface DD-IS, and the lower part (or the lower side) may be defined in a direction away from the display surface DD-IS.

As used herein, a component is “directly arranged (or disposed)/directly formed” on the other component refers to that a third intervening component is not arranged between the component and the other component. For example, the term “directly arranged (or disposed)/directly formed” on the other component refers to that one component is in “contact” with the other component.

FIG. 2 is a cross-sectional view illustrating a portion taken along the line I-I′ in FIG. 1. FIG. 2 may be a cross-sectional view of a display device according to one or more embodiments.

The display device DD may include a display panel DP and an optical layer PP arranged on the display panel DP. The display panel DP may include a base layer BS, a circuit layer DP-CL arranged on the base layer BS, a display element layer DP-EL arranged on the circuit layer DP-CL, and an encapsulation layer TFE arranged on the display element layer DP-EL.

The display panel DP may be a constitution substantially generating an image. The display panel DP may be a luminous type or kind of display panel. For example, the display panel DP may be a quantum dot display panel including a quantum dot light-emitting element.

The base layer BS may be a member providing a base surface on which the circuit layer DP-CL is arranged. The base layer BS may be a rigid substrate, or a flexible substrate capable of being bent, folded, and/or rolled. The base layer BS may be a glass substrate, a metal substrate, a polymer substrate, and/or the like. However, embodiments of the present disclosure are not limited thereto, and the base layer BS may be an inorganic layer, an organic layer, or a complex material layer (e.g., including both inorganic and organic materials).

The circuit layer DP-CL may be arranged on the base layer BS. The circuit layer DP-CL may include an insulating layer, a semiconductor pattern, a conductive pattern, a signal line, and/or the like. The insulating layer, the semiconductor layer, and the conductive layer may be formed on the base layer BS through methods such as coating and/or deposition, and then the insulating layer, the semiconductor layer, and the conductive layer may be selectively patterned through a plurality of photolithography processes. Then, the semiconductor pattern, the conductive pattern, and the signal line, each included in the circuit layer DP-CL, may be formed.

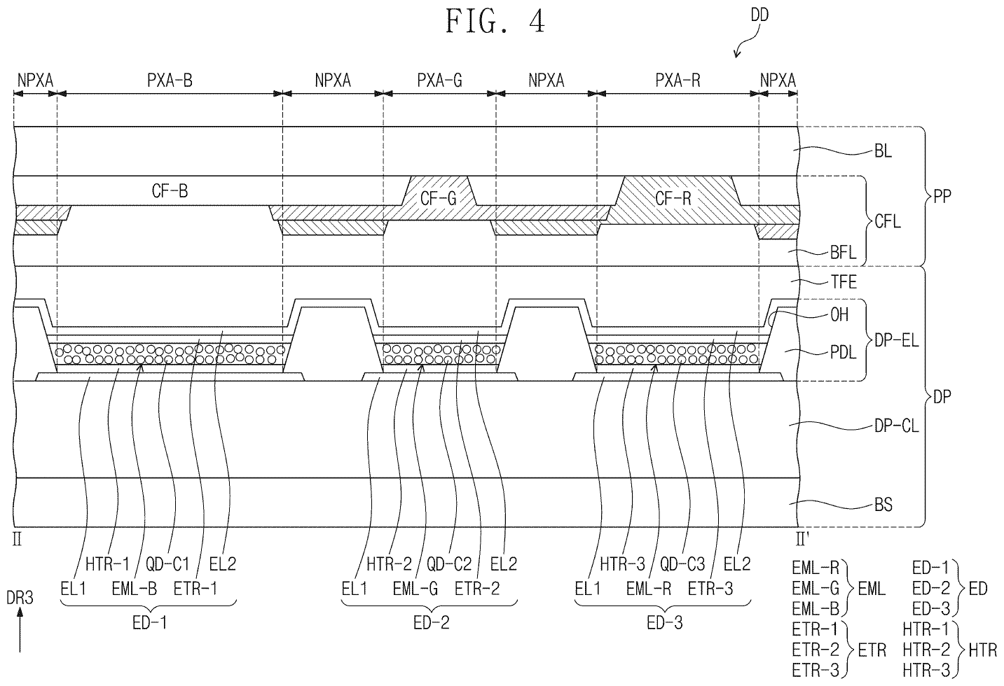

The display element layer DP-EL may be arranged on the circuit layer DP-CL. The display element layer DP-EL may include a pixel definition film PDL (FIG. 4) and first to third light-emitting elements ED-1, ED-2, and ED-3 (FIG. 4), which will be described in more detail later. For example, the display element layer DP-EL may include an organic emission material, an inorganic emission material, an organic-inorganic emission material, a quantum dot, a quantum rod, a micro LED, or a nano LED. In some embodiments, the display element layer DP-EL may include a quantum dot (e.g., a plurality of quantum dots) as an emission material.

The encapsulation layer TFE may protect the display element layer DP-EL from foreign materials such as moisture, oxygen, and/or dust particles. The encapsulation layer TFE may include at least one inorganic layer. The encapsulation layer TFE may include a structure, in which an inorganic layer, an organic layer, and an inorganic layer are sequentially stacked.

The optical layer PP may be arranged on the display panel DP to thereby control reflection of external light on the display panel. The optical layer PP may include, for example, a polarizing layer or a color filter layer CFL (FIG. 4). In one or more embodiments, unlike what is illustrated in the drawings, the optical layer PP may not be provided.

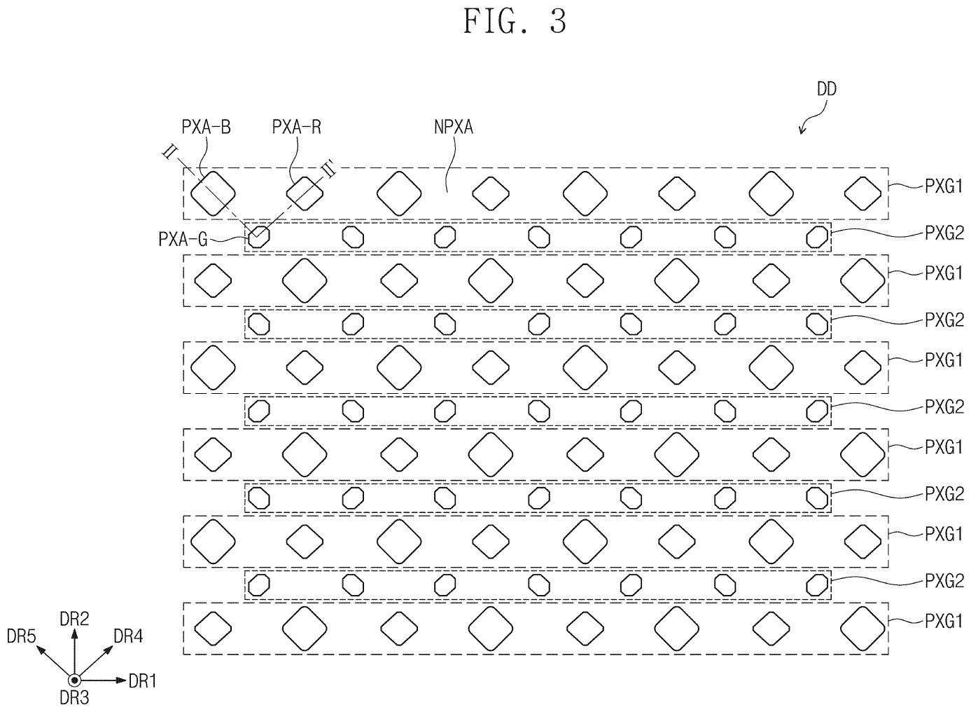

FIG. 3 is a plan view illustrating a display device according to one or more embodiments. FIG. 4 is a cross-sectional view illustrating a portion taken along the line II-II′ in FIG. 3. FIG. 4 is a cross-sectional view illustrating a display device according to one or more embodiments.

Referring to FIG. 3 and FIG. 4, the display device DD may include a peripheral region NPXA and emission regions PXA-R, PXA-G, and PXA-B. The emission regions PXA-R, PXA-G, and PXA-B may be each a region emitting light generated in the light-emitting elements ED-1, ED-2, and ED-3, respectively. The emission regions PXA-R, PXA-G, and PXA-B may have different areas, and in this case, the area may refer to an area on a plane.

The emission regions PXA-R, PXA-G, and PXA-B may be divided into a plurality of groups depending on colors of light generated in the light-emitting elements ED-1, ED-2, and ED-3. FIG. 3 and FIG. 4 illustrate three emission regions PXA-R, PXA-G, and PXA-B for emitting red light, green light, and blue light, respectively. For example, the display device DD according to one or more embodiments may include a red emission region PXA-R, a green emission region PXA-G, and a blue emission region PXA-B, which are distinct from each other.

The light-emitting element ED may include a plurality of light-emitting elements ED-1, ED-2, and ED-3, emitting light in different wavelength regions. The light-emitting element ED may include a plurality of the light-emitting elements. The light-emitting element ED may include a first light-emitting element ED-1, a second light-emitting element ED-2, and a third light-emitting element ED-3. The plurality of light-emitting elements ED-1, ED-2, and ED-3 may be to emit light with different colors. For example, the display panel DP may include a first light-emitting element ED-1 emitting red light, a second light-emitting element ED-2 emitting green light, and a third light-emitting element ED-3 emitting blue light. However, embodiments of the present disclosure are not limited thereto, and the first to third light-emitting elements ED-1, ED-2, and ED-3 may be to emit light in substantially the same wavelength region, or at least one may be to emit light in a different wavelength region.

In the display device DD according to one or more embodiments, illustrated in FIG. 3 and FIG. 4, the emission regions PXA-R, PXA-G, and PXA-B may have, in the emission layers EML-B, EML-G, and EML-R of the light-emitting elements ED-1, ED-2, and ED-3, different areas depending on the colors of light emitted. The blue emission region PXA-B of the first light-emitting element ED-1, emitting blue light, may have the greatest area, and the green emission region PXA-G of the second light-emitting element ED-2, emitting green light, may have the smallest area. However, embodiments of the present disclosure are not limited thereto, and the emission regions PXA-R, PXA-G, and PXA-B may be to emit light of colors other than red, green, and blue light. In one or more embodiments, the emission regions PXA-R, PXA-G, and PXA-B may have the same areas or may be provided at a different area ratio from what is illustrated in FIG. 3.

The emission regions PXA-R, PXA-G, and PXA-B may each be a region distinguished by a pixel definition film PDL. The peripheral regions NPXAs may be regions between the neighboring emission regions PXA-R, PXA-G, and PXA-B, and correspond to the pixel definition film PDL. The emission regions PXA-R, PXA-G, and PXA-B may each correspond to pixels.

The pixel definition film PDL may define the emission regions PXA-R, PXA-G, and PXA-B. The emission regions PXA-R, PXA-G, and PXA-B and the peripheral region NPXA may be separated by the pixel definition film PDL.

The blue emission regions PXA-Bs and the red emission regions PXA-Rs may be arranged by turns along the first directional axis DR1 to form a first group PXG1. The green emission regions PXA-Gs may be arranged along the first directional axis DR1 to form a second group PXG2. The first group PXG1 may be arranged apart from the second group PXG2 in a direction of the second directional axis DR2. The first group PXG1 and the second group PXG2 may each be provided in the plurality. The first groups PXG1s and the second groups PXG2s may be arranged by turns along the second directional axis DR2.

One red emission region PXA-R may be arranged apart from one green emission region PXA-G in a direction of the fourth directional axis DR4. One blue emission region PXA-B may be arranged apart from one green emission region PXA-G in a direction of the fifth directional axis DR5. The direction of the fourth directional axis DR4 may be a direction between the direction of the first directional axis DR1 and the direction of the second directional axis DR2. The fifth directional axis DR5 may cross the fourth directional axis DR4 and may be a direction inclined with respect to the second directional axis DR2.

In one or more embodiments, an arrangement structure of the emission regions PXA-R, PXA-G, and PXA-B is not limited to an arrangement structure illustrated in FIG. 3. For example, in the emission regions PXA-R, PXA-G, and PXA-B, the red emission region PXA-R, the green emission region PXA-G, and the blue emission region PXA-B may be arranged by turns along the first directional axis DR1. In one or more embodiments, shapes of the emission regions PXA-R, PXA-G, and PXA-B on the plane are not limited to what is illustrated and may be defined as a different shape from what is illustrated.

In FIG. 4, the base layer BS may include a single-layer or multilayer structure. For example, the base layer BS may include a first synthetic resin layer, an intermediate layer having a multilayer or single layer structure, and a second synthetic resin layer, which are sequentially stacked. The intermediate layer may be referred to as a base barrier layer. The intermediate layer may include a silicon oxide (SiOₓ) layer, and an amorphous silicon (a-Si) layer arranged on the silicon oxide layer, but the present disclosure is not limited thereto. For example, the intermediate layer may include at least one among a silicon oxide layer, a silicon nitride layer, a silicon oxynitride layer, and an amorphous silicon layer.

The first and second synthetic resin layers may each include a polyimide-based resin. In one or more embodiments, the first and second synthetic resin layers may each include at least one among an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. As used herein, a term “˜˜”-based resin refers to a resin that contains a “˜˜” functional group.

The circuit layer DP-CL may be arranged on the base layer BS and may include a plurality of transistors. The transistors may each include a control electrode, an input electrode, and an output electrode. For example, the circuit layer DP-CL may include a switching transistor and a driving transistor for driving the light-emitting elements ED-1, ED-2, and ED-3 of the display element layer DP-EL.

The display element layer DP-EL may include a pixel definition film, PDL, and first to third light-emitting elements ED-1, ED-2, and ED-3. In the pixel definition film PDL, a pixel opening part OH may be defined. The pixel definition film PDL may separate the first to third light-emitting elements ED-1, ED-2, and ED-3. Emission layers EML-R, EML-G, and EML-B of the first to third light-emitting elements ED-1, ED-2, and ED-3 may be arranged in the pixel opening part OH defined in the pixel definition film PDL to thereby be distinguished (e.g., separated).

The pixel definition film PDL may be formed of a polymer resin. For example, the pixel definition film PDL may be formed to include a polyacrylate-based resin or a polyimide-based resin. In one or more embodiments, the pixel definition film PDL may be formed to further include an inorganic material in addition to the polymer resin. In one or more embodiments, the pixel definition film PDL may be formed to include a light-absorption material or may be formed to include a black pigment or a black dye. The pixel definition film PDL formed to include the black pigment or the black dye may achieve (e.g., may be) a black pixel definition film. When the pixel definition film PDL is formed, carbon black and/or the like may be utilized as the black pigment or the black dye, but embodiments of the present disclosure are not limited thereto.

In one or more embodiments, the pixel definition film PDL may be formed of inorganic materials. For example, the pixel definition film PDL may be formed of inorganic materials such as silicon nitride (SiNₓ), silicon oxide (SiOₓ), and/or silicon oxynitride (SiOₓN_{y}).

The light-emitting element ED may include a plurality of the light-emitting elements. The light-emitting element ED may include a first light-emitting element ED-1, a second light-emitting element ED-2, and a third light-emitting element ED-3. The light-emitting elements ED-1, ED-2, and ED-3 may include a first electrode EL1, a hole transport region HTR (HTR-1, HTR-2, or HTR-3) arranged on the first electrode EL1, an emission layer EML (EML-B, EML-G, or EML-R) arranged on the hole transport region HTR (HTR-1, HTR-2, or HTR-3), an electron transport region ETR (ETR-1, ETR-2, or ETR-3) arranged on the emission layer EML (EML-B, EML-G, or EML-R), and a second electrode EL2 arranged on the electron transport region ETR (ETR-1, ETR-2, and ETR-3). The emission layers EML may include a first emission layer EML-B, a second emission layer EML-G, and a third emission layer EML-G. The hole transport region HTR may include a first hole transport region HTR-1, a second hole transport region HTR-2, and a third hole transport region HTR-3. The electron transport region ETR may include a first electron transport region ETR-1, a second electron transport region ETR-2, and a third electron transport region ETR-3.

The first electrode EL1 may be exposed in the pixel opening part OH of the pixel definition film PDL. The first electrode EL1 has conductivity (e.g., is a conductor). The first electrode EL1 may be formed of a metal material, a metal alloy, or a conductive compound. The first electrode EL1 may be a cathode or an anode. However, embodiments of the present disclosure are not limited thereto. In one or more embodiments, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn; a compound of two or more selected therefrom; a mixture of two or more selected therefrom; and an oxide thereof.

When the first electrode EL1 is a transmissive electrode, the first electrode EL1 may include a transparent metal oxide, for example, indium tin oxide (ITO), indium zinc oxide (IZO), zinc oxide (ZnO), indium tin zinc oxide (ITZO), and/or the like. When the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, or a compound or mixture thereof (for example, a mixture of Ag and Mg). In one or more embodiments, the first electrode EL1 may have a multilayered structure including a reflective film or transflective film, formed of the materials previously described, and a transparent conductive film formed of indium tin oxide (ITO), indium zinc oxide (IZO), zinc oxide (ZnO), indium tin zinc oxide (ITZO), and/or the like. For example, the first electrode EL1 may have a three-layered structure of ITO/Ag/ITO, but the present disclosure is not limited thereto. In one or more embodiments, the first electrode EL1 may include one or more of the above-described metal materials, a combination of two or more metal materials selected from among the above-described metal materials, an oxide of the above-described metal materials, and/or the like, but embodiments of the present disclosure are not limited thereto. The first electrode EL1 may have a thickness of about 700 Å to about 10000 Å. For example, the first electrode EL1 may have a thickness of about 1000 Å to about 3000 Å.

The second electrode EL2 may be a common electrode. The second electrode EL2 may be an anode or a cathode, but embodiments of the present disclosure are not limited thereto. For example, in a case where the first electrode EL1 is an anode, the second electrode EL2 may be a cathode, and in a case where the first electrode EL1 is a cathode, the second electrode EL2 may be an anode. The second electrode EL2 may include: at least one selected from among Ag, Mg, Cu, Al, Pt, Pd, Au, Ni, Nd, Ir, Cr, Li, Ca, LiF, Mo, Ti, W, In, Sn, and Zn; a compound of two or more selected therefrom; a mixture of two or more selected therefrom; and an oxide thereof.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), and/or the like.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/AI, Mo, Ti, Yb, W, a compound and/or a (e.g., any suitable) mixture including the same (for example, AgMg, AgYb, or MgYb). In one or more embodiments, the second electrode EL2 may have a multilayer structure including a reflective film or a transflective film, formed of the above-described materials, and a transparent conductive film formed of indium tin oxide (ITO), indium zinc oxide (IZO), zinc oxide (ZnO), indium tin zinc oxide (ITZO), and/or the like. For example, the second electrode EL2 may include one or more of the above-described metal materials, a combination of two or more metal materials selected from among the above-described metal materials, or an oxide of the above-described metal materials.

In some embodiments, the second electrode EL2 may be connected to an auxiliary electrode. If the second electrode EL2 is connected to the auxiliary electrode, a resistance of the second electrode EL2 may decrease.

The emission layers EML-B, EML-G, and EML-R may be arranged between the first electrode EL1 and the second electrode EL2. The first light-emitting element ED-1 may include the first emission layer EML-B, the second light-emitting element ED-2 may include the second emission layer EML-G, and the third light-emitting element ED-3 may include the third emission layer EML-R. The first emission layer EML-B may include (e.g., a plurality of) a first quantum dot QD-C1. The second emission layer EML-G may include (e.g., a plurality of) a second quantum dot QD-C2. The third emission layer EML-R may include (e.g., a plurality of) the third quantum dot QD-C3.

Each of the quantum dots QD-C1, QD-C2, and QD-C3 included in the emission layers EML-B, EML-G, and EML-R may be stacked to form a layer. FIG. 4 illustrates that the quantum dots QD-C1, QD-C2, and QD-C3, each having a cross-section of a circular shape, are arranged to form approximately or about two layers, but embodiments of the present disclosure are not limited thereto. For example, the arrangement of the quantum dots QD-C1, QD-C2, and QD-C3 may differ depending on the thicknesses of the emission layers EML-R, EML-G, and EML-B, shapes of the quantum dots QD-C1, QD-C2, and QD-C3 included in the emission layers EML-R, EML-G, and EML-B, an average diameter of the quantum dots QD-C1, QD-C2, and QD-C3, and/or the like. For example, the quantum dots QD-C1, QD-C2, and QD-C3 may be arranged to be neighboring (e.g., adjacent to) each other, thereby forming a single layer, or forming a plurality of layers such as two layers, three layers, etc.

The first quantum dot QD-C1 of the first light-emitting element ED-1 may be to emit blue light. The second quantum dot QD-C2 of the second light-emitting element ED-2 may be to emit green light. The third quantum dot QD-C3 of the third light-emitting element ED-3 may be to emit red light. The quantum dots QD-C1, QD-C2, and QD-C3 may each include a core and a shell around (e.g., surrounding) the core. Therefore, the quantum dots QD-C1, QD-C2, and QD-C3 may each include a core-shell structure. In one or more embodiments, the cores of the quantum dots QD-C1, QD-C2, and QD-C3 may include different materials. In one or more embodiments, the cores of the quantum dots QD-C1, QD-C2, and QD-C3 may include the same material. In one or more embodiments, two cores selected from among the cores of the quantum dots QD-C1, QD-C2, and QD-C3 may include the same material, and the rest may include a different material.

FIG. 4 illustrates that the first to third quantum dots QD-C1, QD-C2, and QD-C3 each have a similar diameter, but embodiments of the present disclosure are not limited thereto. Each diameter of the first to third quantum dots QD-C1, QD-C2, and QD-C3 may be different. For example, the first quantum dot QD-C1 of the first light-emitting element ED-1, which emits light in a relatively shorter wavelength region, may have a relatively smaller average diameter than the second quantum dot QD-C2 of the second light-emitting element ED-2 and the third quantum dot QD-C3 of the third light-emitting element ED-3, which emit light in a relatively longer wavelength region. The average diameter corresponds to an arithmetic mean value of particle diameters of a plurality of quantum dots. The particle diameter of the quantum dot may be an average value of widths of the quantum dot particle on the cross-section.

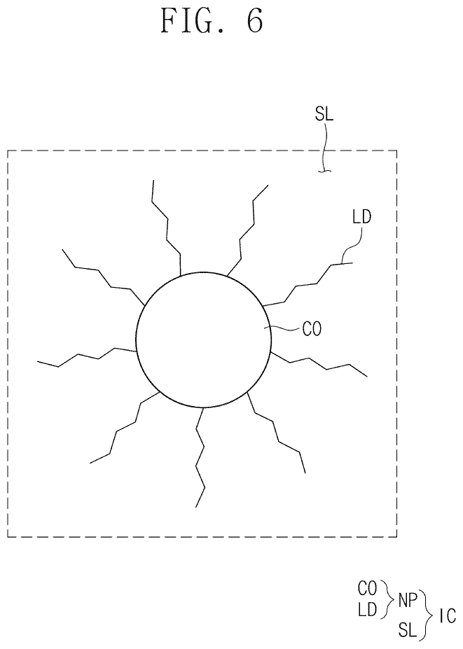

In one or more embodiments, the electron transport regions ETR-1, ETR-2, and ETR-3 may include a nanoparticle NP (FIG. 6). The nanoparticle NP (FIG. 6) will be described in more detail hereinafter.

The hole transport regions HTR-1, HTR-2, and HTR-3 of the first to third light-emitting elements ED-1, ED-2, and ED-3 may be arranged in the pixel opening part OH to thereby be distinguished (e.g., separated). The first light-emitting element ED-1 may include the first hole transport region HTR-1, the second light-emitting element ED-2 may include the second hole transport region HTR-2, and the third light-emitting element ED-3 may include the third hole transport region HTR-3.

The hole transport regions HTR-1, HTR-2, and HTR-3 may each have a single layer formed of a single material, a single layer formed of a plurality of different materials, or a multilayer structure having a plurality of layers formed of a plurality of different materials. The first to third hole transport regions HTR-1, HTR-2, and HTR-3 may each have a thickness of, for example, about 50 Å to about 15000 Å. The first to third hole transport regions HTR-1, HTR-2, and HTR-3 may each have a thickness of about 100 Å to about 10000 Å, and for example, about 100 Å to about 5000 Å.

The first to third hole transport regions HTR-1, HTR-2, and HTR-3 may further include a suitable hole injection material and/or a suitable hole transport material. For example, the first to third hole transport regions HTR-1, HTR-2, and HTR-3 may include a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate (PEDOT/PSS), polyaniline/dodecylbenzenesulfonic acid (PANI/DBSA), polyaniline/camphor sulfonicacid (PANI/CSA), polyaniline/poly(4-styrenesulfonate (PANI/PSS), N,N′-di(naphthalene-1-yl)-N,N′-diphenyl-benzidine (NPB), polyetherketone containing triphenylamine (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), and/or the like.

In one or more embodiments, the first to third hole transport regions HTR-1, HTR-2, and HTR-3 may include carbazole-based derivatives such as N-phenylcarbazole, polyvinyl carbazole, a fluorene-based derivatives, triphenylamine-based derivatives such as N,N′-bis(3-methylphenyl)-N,N′-diphenyl-[1,1′-biphenyl]-4,4′-diamine (TPD), 4,4′,4″-tris(N-carbazolyl)triphenylamine (TCTA), N,N′-di(naphthalene-1-yl)-N,N′-diplienyl-benzidine (NPB), 4,4′-cyclohexylidene bis[N,N-bis(4-methylphenyl)benzenamine] (TAPC), 4,4′-bis[N,N′-(3-tolyl)amino]-3,3′-dimethylbiphenyl (HMTPD), 9-(4-tert-Butylphenyl)-3,6-bis(triphenylsilyl)-9H-carbazole (CzSi), 9-phenyl-9H-3,9′-bicarbazole (CCP), 1,3-bis(N-carbazolyl)benzene (mCP), 1,3-bis(1,8-dimethyl-9H-carbazol-9-yl)benzene (DCP), and/or the like.

The electron transport regions ETR-1, ETR-2, and ETR-3 of the first to third light-emitting elements ED-1, ED-2, and ED-3 may be arranged in the pixel opening part OH to thereby be distinguished (e.g., separated). The first light-emitting element ED-1 may include a first electron transport region ETR-1, the second light-emitting element ED-2 may include the second electron transport region ETR-2, and the third light-emitting element ED-3 may include the third electron transport region ETR-3.

The first to third electron transport regions ETR-1, ETR-2, and ETR-3 may each have a single layer formed of a single material, a single layer formed of a plurality of different materials, or a multilayer structure having a plurality of layers formed of a plurality of different materials. The first to third electron transport regions ETR-1, ETR-2, and ETR-3 may each have a thickness of, for example, about 1000 Å to about 1500 Å.

The first to third electron transport regions ETR-1, ETR-2, and ETR-3 may further include a suitable electron injection material and/or a suitable electron transport material in addition to the above-described nanoparticle NP (FIG. 6). For example, the electron transport region ETR may include an anthracene-based compound. In one or more embodiments, the first to third electron transport regions ETR-1, ETR-2, and ETR-3 may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), or a (e.g., any suitable) mixture thereof. In one or more embodiments, the electron transport region ETR may include 2,9-dimethyl-4,7-diphenyl-1,10-phenanthroline (BCP), diphenyl(4-(triphenylsilyl)phenyl)phosphine oxide (TSPO1), 4,7-diphenyl-1,10-phenanthroline (Bphen), and/or the like.

The encapsulation layer TFE may include at least one inorganic film (hereinafter, referred to as an encapsulation inorganic film). In one or more embodiments, the encapsulation layer TFE may include at least one organic film (hereinafter, referred to as an encapsulation organic film) and at least one encapsulation inorganic film.

The encapsulation inorganic film may protect the display element layer DP-EL from moisture/oxygen, and the encapsulation organic film may protect the display element layer DP-EL from a foreign material such as a dust particle. The encapsulation inorganic film may include silicon nitride, silicon oxynitride, silicon oxide, titanium oxide, aluminum oxide, and/or the like, but the present disclosure is not particularly limited thereto. The encapsulation organic film may include an acrylate-based compound, an epoxy-based compound, and/or the like. The encapsulation organic film may include a photopolymerizable organic material, but the present disclosure is not particularly limited.

The optical layer PP may include a base substrate BL and a color filter layer CFL. The base substrate BL may be a member providing a base surface on which the color filter layer CFL is arranged. The base substrate BL may be a glass substrate, a metal substrate, a plastic substrate, and/or the like. However, embodiments of the present disclosure are not limited thereto, and the base substrate BL may be an inorganic layer, an organic layer, or a complex material layer (e.g., including both inorganic and organic materials).

The color filter layer CFL may include first to third filters CF-B, CF-G, and CF-R. The first to third filters CF-B, CF-G, and CF-R may be arranged so as to correspond to the first to third light-emitting elements ED-1, ED-2, and ED-3, respectively. For example, the first filter CF-B may be a blue filter, the second filter CF-G may be a green filter, and the third filter CF-R may be a red filter. The first to third filters CF-B, CF-G, and CF-R may each be arranged so as to correspond to the first to third pixel regions PXA-R, PXA-B, and PXA-G, respectively.

The first to third filters CF-B, CF-G, and CF-R may each include a polymer photosensitive resin and a pigment or dye. The first filter CF-B, the second filter CF-G, the third filter CF-R may include a blue pigment or a blue dye, a green pigment or a green dye, and a red pigment or a red dye, respectively. However, embodiments of the present disclosure are not limited thereto, and the first filter CF-B may include no pigment or no dye. The first filter CF-B may include a polymer photosensitive resin and may include no pigment or no dye. The first filter CF-B may be transparent. The first filter CF-B may be formed of a transparent photosensitive resin.

The color filter layer CFL may further include a buffer layer BFL. For example, the buffer layer BFL may be a protective layer protecting the first to third filters CF-B, CF-G, and CF-R. The buffer layer BFL may be an inorganic layer including at least one inorganic material among silicon nitride, silicon oxide, and silicon oxynitride. The buffer layer BFL may be formed by a single layer or a plurality of layers.

In one or more embodiments, the second filter CF-G, and the third filter CF-R may each be a yellow filter. The second filter CF-G and the third filter CF-R may be provided as a single unit without being distinguished from each other.

In one or more embodiments, the color filter layer CFL may further include a light-blocking part. The light-blocking part may be a black matrix. The light-blocking part may be formed including an organic light-blocking material or an inorganic light-blocking material, containing a black pigment or a black dye. The light-blocking part may prevent or reduce a light leakage, and separate (e.g., act as) a barrier between adjacent filters CF-B, CF-G, and CF-R.

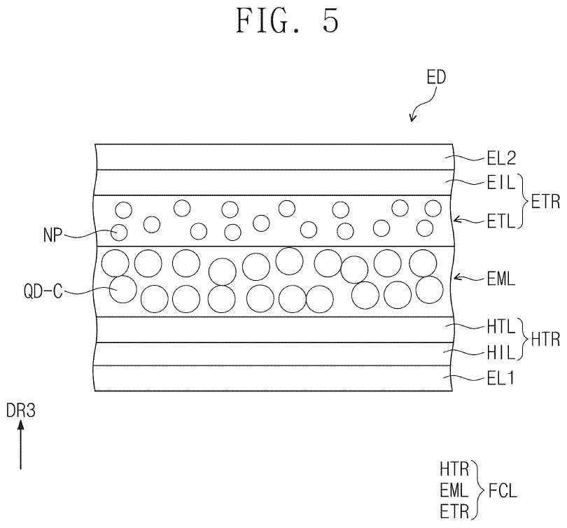

FIG. 5 is a cross-sectional view illustrating a light-emitting element ED according to one or more embodiments. The light-emitting element ED described with reference to FIG. 5 may be similarly applied to at least one among the first to third light-emitting elements ED-1, ED-2 and ED-3 illustrated in FIG. 4.

Referring to FIG. 5, the light-emitting element ED may include a first electrode EL1, a functional layer FCL, and a second electrode EL2, which are sequentially stacked. The functional layer FCL may include a hole transport region HTR, an emission layer EML, and an electron transport region ETR. The hole transport region HTR may include a hole injection layer HIL and a hole transport layer HTL. The hole injection layer HIL may be arranged on the first electrode EL1, and the hole transport layer HTL may be arranged on the hole injection layer HIL. The electron transport region ETR may include an electron transport layer ETL and an electron injection layer EIL. The electron injection layer EIL may be arranged on the electron transport layer ETL, and the second electrode EL2 may be arranged on the electron injection layer EIL. In the light-emitting element ED, the functional layer FCL may include a nanoparticle NP according to one or more embodiments. In the light-emitting element ED, the electron transport region ETR may include a nanoparticle NP according to one or more embodiments. At least one selected from among the electron transport layer ETL and the electron injection layer EIL may include a nanoparticle NP according to one or more embodiments. For example, as illustrated in FIG. 5, the electron transport layer ETL may include a nanoparticle NP according to one or more embodiments. In one or more embodiments, the electron transport layer ETL and the electron injection layer EIL may each include a nanoparticle according to one or more embodiments. The electron transport region ETR including the nanoparticle NP according to one or more embodiments has an improved differences between an injection rate and a transport rate of electrons, and between an injection rate and a transport rate of holes and thus may contribute to improvements in light efficiency of the light-emitting element ED.

The emission layer EML may include a quantum dot QD-C. Hereinafter, the description of the quantum dot QD-C may be similarly applied to the first to third quantum dots QD-C1, QD-C2, and QD-C3 illustrated in FIG. 4.

As used herein, the quantum dot QD-C refers to a crystal of a semiconductor compound. The quantum dot QD-C may be to emit light with one or more suitable emission wavelengths depending on a size (e.g., diameter) of the crystal. The quantum dot QD-C may have a diameter of, for example, about 1 nm to about 10 nm.

The quantum dot QD-C may be synthesized by a wet chemical process, a metal organic chemical vapor deposition process, a molecular beam epitaxy process, a similar process thereto, and/or the like. The wet chemical process is a method for growing a quantum dot QD-C particle crystal after mixing an organic solvent and a precursor material. During the growth of the crystal, the organic solvent may naturally serve as a dispersant coordinated to a surface of the quantum dot QD-C crystal and may control the growth of the crystal. Therefore, the wet chemical process may control the growth of the quantum dot QD-C particle through an easier and relatively lower-cost process, than the vapor deposition process such as a metal organic chemical vapor deposition (MOCVD) or a molecular beam epitaxy (MBE).

The quantum dot may include a Group II-VI semiconductor compound, a Group I-II-VI-semiconductor compound, a Group II-IV-VI compound; a Group I-II-IV-VI semiconductor compound, a Group III-V semiconductor compound, a Group III-VI semiconductor compound, a Group I-III-VI semiconductor compound, a Group IV-VI semiconductor compound, a Group II-IV-V semiconductor compound, a Group IV element or compound, or a (e.g., any suitable) combination thereof. As used herein, a “Group” refers to a group in the IUPAC periodic table.

Examples of the Group II-VI semiconductor compound may include: a binary compound such as CdS, CdSe, CdTe, ZnS, ZnSe, ZnTe, ZnO, HgS, HgSe, HgTe, MgSe, and/or MgS; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and/or MgZnS; a quaternary compound such as CdZnSeS, CdZnSeTe, CdZnSTe, CdHgSeS, CdHgSeTe, CdHgSTe, HgZnSeS, HgZnSeTe, and/or HgZnSTe; or a (e.g., any suitable) combination thereof. In one or more embodiments, the Group II-VI semiconductor compound may further include a Group I metal and/or a Group IV element. The Group I-II-VI compound may be selected from among CuSnS and CuZnS, and as the Group II-IV-VI compound, ZnSnS and/or the like may be selected. The Group I-II-IV-VI compound may be selected from among quaternary compounds selected from among the group including (e.g., consisting of) Cu₂ZnSnS₂, Cu₂ZnSnS₄, Cu₂ZnSnSe₄, Ag₂ZnSnS₂ and/or a (e.g., any suitable) mixture (e.g., combination) thereof.

Examples of the Group III-V semiconductor compound may include: binary compounds such as GaN, GaP, GaAs, GaSb, AlN, AlP, AlAs, AlSb, InN, InP, InAs, and/or InSb; ternary compounds such as GaNP, GaNAs, GaNSb, GaPAs, GaPSb, AlNP, AlNAs, AlNSb, AlPAs, AlPSb, InGaP, InNP, InAlP, InNAs, InNSb, InPAs, and/or InPSb; quaternary compounds such as GaAlNP, GaAlNAs, GaAlNSb, GaAlPAs, GaAlPSb, GaInNP, GaInNAs, GalnNSb, GaInPAs, GalnPSb, InAlNP, InAlNAs, InAlNSb, InAlPAs, and/or InAlPSb; and a (e.g., any suitable) combination thereof. In one or more embodiments, the Group III-V semiconductor compound may further include a Group II element. Examples of the Group III-V semiconductor compound further containing the Group II element may include InZnP, InGaZnP, InAlZnP, and/or the like.

Examples of the Group III-VI semiconductor compound may include: binary compounds such as GaS, Ga₂S₃, GaSe, Ga₂Se₃, GaTe, InS, InSe, In₂Se₃, and/or InTe; ternary compounds such as InGaS₃, and/or InGaSe₃; and a (e.g., any suitable) combination thereof.

Examples of the Group I-III-VI semiconductor compound may include: ternary compounds such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, and/or AgAlO₂; quaternary compounds such as AgInGaS₂, and/or AgInGaSe₂; and a (e.g., any suitable) combination thereof.

Examples of the Group IV-VI semiconductor compounds may include: binary compounds such as SnS, SnSe, SnTe, PbS, PbSe, and/or PbTe; ternary compounds such as SnSeS, SnSeTe, SnSTe, PbSeS, PbSeTe, PbSTe, SnPbS, SnPbSe, and/or SnPbTe; quaternary compounds such as SnPbSSe, SnPbSeTe, and/or SnPbSTe; and a (e.g., any suitable) combination thereof.

Examples of the Group II-IV-V semiconductor compound may include ternary compounds selected from among the group including (e.g., consisting of) ZnSnP, ZnSnP₂, ZnSnAs₂, ZnGeP₂, ZnGeAs₂, CdSnP₂, CdGeP₂, and/or a (e.g., any suitable) mixture thereof.

Examples of the Group IV element or compound may include monatomic compounds such as Si, and/or Ge; binary compounds such as SiC, and/or SiGe, and a (e.g., any suitable) combination thereof.

Each element contained in the multi-component compound such as the binary compound, the ternary compound and/or the quaternary compound may present in particles at a substantially uniform concentration or a non-uniform concentration. For example, the formulas above refer to a type or kind of element included in the compound, and an element ratio in the compound may differ. For example, AgInGaS₂ may refer to AgInₓGa₁₋ₓS₂ (where, x is a real number of 0 to 1).

In one or more embodiments, the quantum dot QD-C may have a single structure in which the concentration of each element contained in the corresponding quantum dot QD-C is substantially uniform, or may have a dual structure of a core-shell. For example, a material contained in the core may be different from a material contained in the shell.

The shell of the quantum dot QD-C may serve as a protective layer for preventing or substantially preventing the core from a chemical alteration to maintain semiconductor characteristics and/or serve as a charging layer for imparting electrophoretic characteristics to the quantum dot. The shell may have a single layer or a multilayer. The core/shell structure may have a concentration gradient that the concentration of the elements present in the shell may decrease gradually toward the core.

Examples of the shell of the quantum dot QD-C may include an oxide of a metal or a non-metal, a semiconductor compound, and/or a (e.g., any suitable) combination thereof. Examples of the oxide of a metal or a non-metal may include: binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO; ternary compounds such as MgAl₂O₄, CoFe₂O₄, NiFe₂O₄, and/or CoMn₂O₄; and a (e.g., any suitable) combination thereof. Examples of the semiconductor compound may include the Group III-VI semiconductor compound, the Group II-VI semiconductor compound, the Group III-V semiconductor compound, the Group III-VI semiconductor compound, the Group I-III-VI semiconductor compound, the Group IV-VI semiconductor compound, and a (e.g., any suitable) combination thereof, as described in this specification. For example, the semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb, and/or a (e.g., any suitable) combination thereof.

Each element contained in a multi-component compound such as the binary compound and/or the ternary compound may be present in particles at a substantially uniform concentration or a non-uniform concentration. For example, the formulas above refer to a type or kind of the elements contained in the compound, and an element ratio within the compound may differ.

The quantum dot may have a full width of half maximum (FWHM) of an emission wavelength spectrum of about 45 nm or less, about 40 nm or less, or about 30 nm or less, and if (e.g., when) FWHM falls within these ranges, color purity and/or color reproductivity may be improved. In one or more embodiments, light emitted through the quantum dot may be emitted in all directions, and thus an optical viewing angle may be improved.

In one or more embodiments, the shape of the quantum dot is not particularly limited as long as it is a suitable shape (e.g., commonly utilized) in the art, for example, the quantum dots in the shape of spherical, pyramidal, multi-arm, or cubic nanoparticles, nanotubes, nanowires, nanofibers, nanoplatelets, and/or the like may be utilized.

An energy band gap may be adjusted by adjusting the quantum dot size (e.g., diameter) or the element ratio in the quantum dot compound, and thus light with various suitable wavelengths may be emitted in the quantum dot emission layer. Therefore, because the quantum dots as previously described (quantum dots having different sizes or having different element ratios in the quantum dot compound) are utilized, light-emitting elements emitting light with various suitable wavelengths may be achieved. For example, adjustments in the sizes of the quantum dot and the element ratios in the quantum dot compound may be selected for red, green, and/or blue light to be emitted. In one or more embodiments, the quantum dots may be configured to emit white light by combining one or more suitable colors of light.

FIG. 6 illustrates a portion of an ink composition according to one or more embodiments.

An ink composition IC illustrated in FIG. 6 may be utilized as materials for forming the electron transport region ETR of the light-emitting element ED illustrated in FIG. 5. A method for forming the electron transport region ETR may include: forming a nanoparticle NP by bonding a ligand LD to a surface of a core CO dispersed in a solvent SL; providing the ink composition IC in which the nanoparticle NP is formed onto an emission layer EML; and drying off the solvent SL.

Referring to FIG. 5 and FIG. 6 together, the ink composition IC according to one or more embodiments includes the nanoparticle NP and the solvent SL.

The nanoparticle NP includes the core CO and the ligand LD. The nanoparticle NP may be composed of (e.g., consist of or include only) the core CO and the ligand LD. The nanoparticle NP may be contained in the electron transport region ETR, and may appropriately or suitably adjust an electron transport and a transport rate thereof. In the light-emitting element ED, if (e.g., when) the electron transport and the transport rate are appropriately or suitably adjusted to thereby reduce a difference between the electron transport rate and the hole transport rate, charge imbalance in the element may be improved, and thus efficiency and lifespan of the element may be improved.

The nanoparticle NP may be doped with a metal element. When the nanoparticle NP is doped with a metal element, transportation of electrons to the core CO of the nanoparticle NP from the outside may be blocked or reduced, and thus stability of the nanoparticle NP may be improved. The metal element may include at least one among Zn, Mg, Li and Na. For example, the metal element may be Mg.

The solvent SL may be a material capable of dispersing the nanoparticle NP. The solvent SL may serve as a medium capable of enabling a stable deposition process of the nanoparticle NP. The solvent SL may be hydrophobic. For example, the solvent SL may include hexane, cyclohexyl benzene (CHB), or hexadecane.

The core CO includes a metal oxide and serves to transport an electron by being contained in the electron transport region ETR. The core CO includes at least one among a first core compound represented by Formula 1 below, a second core compound represented by Formula 2 below, and a third core compound represented by Formula 3 below. The core CO may be composed of (e.g., consist of or include only) at least one among the first core compound, the second core compound, and the third core compound. For example, the core CO may be composed of (e.g., consist of or include only) the first core compound. In one or more embodiments, the core CO may be composed of (e.g., consist of or include only) the second core compound or composed of (e.g., consist of or include only) the third core compound. The first core compound may include Sn forming a tetravalent cation, Sn forming a divalent cation, and an oxygen atom. The second core compound may include Sn forming a tetravalent cation, Cu forming a monovalent cation, and an oxygen atom. The third core compound may include Sn forming a tetravalent cation, Ni forming a divalent cation, and an oxygen atom.

Sn⁴⁺₁₋ₓSn²⁺ₓO₂₋ₓ Formula 1

In Formula 1, x is greater than about 0, and about 3 or less. For example, x may be about 0.05.

Sn forming a tetravalent cation is an n-type or kind material capable of rapidly transporting electrons. When, in the light-emitting elements ED-1, ED-2, and ED-3 (FIG. 4), the electron transport rate is faster than the hole transport rate, charge imbalance may occur, and thus efficiency and lifespan of the element may decrease. Sn forming a divalent cation is a p-type or kind material having relatively lower electron transport rate than Sn forming the tetravalent cation. When an oxide, in which Sn forming the tetravalent cation is doped with Sn forming the divalent cation, is utilized in the light-emitting element ED (FIG. 4), the electron transport rate is relatively lowered and thus a difference between the electron transport rate and the hole transport rate may be reduced. As a result, in the light-emitting element ED (FIG. 4), a charge imbalance is resolved, and thus efficiency and lifespan of the element may increase.

Sn⁴⁺_{1-y}Cu⁺_{2y}O_{2-y} Formula 2

In Formula 2, y is greater than about 0, and about 3 or less. Cu forming a monovalent cation is a p-type or kind material having a relatively lower electron transport rate than Sn forming a tetravalent cation. When an oxide, in which Sn forming the tetravalent cation is doped with Cu forming the monovalent cation, is utilized in the light-emitting element ED (FIG. 4), the electron transport rate is relatively lowered and thus a difference between the electron transport rate and the hole transport rate may be reduced. As a result, in the light-emitting element ED (FIG. 4), a charge imbalance is resolved, and thus efficiency and lifespan of the element may increase.

Sn⁴⁺_{1-z}Ni²⁺_{z}O_{2-z} Formula 3

In Formula 3, z is greater than about 0, and about 0.3 or less. Ni forming a divalent cation is a p-type or kind material having a relatively lower electron transport rate than Sn forming the tetravalent cation. When an oxide, in which Sn forming the tetravalent cation is doped with Ni forming the divalent cation, is utilized in the light-emitting element ED (FIG. 4), the electron transport rate is relatively lowered and thus a difference between the electron transport rate and the hole transport rate may be reduced. As a result, in the light-emitting element ED (FIG. 4), a charge imbalance is resolved, and thus efficiency and lifespan of the element may increase.

In one or more embodiments, the nanoparticle NP is composed of (e.g., consist of or include only) the first compound, and a peak location of Sn⁴⁺ 3d_{5/2}, measured by X-ray photoelectron spectroscopy (XPS) may be between about 485.0 eV and about 489.0 eV, a peak location of Sn²⁺ 3d_{5/2} may be between about 483.0 eV and about 487.0 eV. A peak intensity ratio of Sn²⁺ 3d_{5/2} to Sn⁴⁺ 3d_{5/2} may be greater than about 0, and about 0.6 or less. An absolute quantum yield of the nanoparticle NP may be greater than about 0%, and about 5% or less. The absolute quantum yield refers to the number of emitted photons to the number of absorbed photons, and, in a case of an organic electroluminescence element, the absolute quantum yield is proportional to the element luminous efficiency.

The ligand LD may be bond to the core CO to improve stability of the core CO, and thus a reverse-reaction caused by oxygen and/or moisture may be inhibited or reduced, and/or the like. In one or more embodiments, an average distance between adjacent cores COs is increased to thereby improve (or reduce) aggregation between particles, and thus jetting characteristics of the ink composition IC may be improved. The ligand LD may impart hydrophobicity to the surface of the nanoparticle NP. The ligand LD may be chemically bonded to the core CO. The ligand LD may be covalently bonded to the surface of the core CO. A plurality of ligands LDs may be bonded to one core CO. The number of the ligands LDs may be greater than the number of the cores COs. The ligand LD may include oleic acid or oleylamine. In one or more embodiments, the ligand LD may be formed of oleic acid or oleylamine. For example, the ligand LD may be composed of oleic acid.

Hereinafter, with reference to Examples and Comparative Examples, a nanoparticle according to one or more embodiments of the present disclosure, and a light-emitting element according to one or more embodiments will be specifically described. In addition, Examples shown below are only for the understanding of the present disclosure, and the scope of the present disclosure is not limited thereto.

### Examples

### 1. Manufacture and Evaluation of Light-Emitting Elements

### (1) Manufacture of Light-Emitting Elements According to One or More Embodiments

Light-emitting elements according to one or more embodiments, containing a nanoparticle according to one or more embodiments, were manufactured utilizing following methods.

### Light-Emitting Element According to Example 1

To synthesize Sn⁴⁺_{0.98}Sn²⁺_{0.02}O_{1.98} nanoparticles, 0.98 mmol of tin (IV) acetate, 0.02 mmol of tin (II) acetate, 3.3 mL of oleic acid, 3.3 mL of oleylamine and 30 mL of xylene were put into a reactor, and then stirred for about 30 minutes in a vacuum atmosphere. After the atmosphere was replaced with N₂, the temperature was raised up to 100° C. and the reactor was maintained for about 30 minutes. 1 mL of DI water was rapidly injected into the stabilized mixture, and then the reaction was maintained for about 5 hours. The temperature of the reaction-terminated mixture was cooled to room temperature, and then an excessive amount of ethanol was injected to thereby precipitate synthesized SnO₂. Then, the obtained solid was dispersed into hexane to synthesize a Sn⁴⁺_{0.98}Sn²⁺_{0.02}O_{1.98} seed.

For further growth of Sn⁴⁺_{0.98}Sn²⁺_{0.02}O_{1.98}, 0.98 mmol of tin (IV) acetate, 0.02 mmol of tin (II) acetate, 3.3 mL of oleic acid and 10 mL of trioctylamine were put into the reactor, the temperature was raised to 120° C., and then the mixture was stirred for about 30 minutes in a vacuum atmosphere. The atmosphere was replaced by N₂, then the Sn⁴⁺_{0.98}Sn²⁺_{0.02}O_{1.98} seed was injected, and then the reaction was maintained for about 1 hour. The temperature of the reaction-terminated Sn⁴⁺_{0.98}Sn²⁺_{0.02}O_{1.98} nanoparticle solution was cooled to room temperature, then the solution was purified twice utilizing hexane and ethanol, and then was dispersed in cyclohexybenzene.

### Light-Emitting Element According to Example 2

To synthesize Sn⁴⁺_{0.95}Sn²⁺_{0.05}O_{1.95} nanoparticles, 0.95 mmol of tin (IV) acetate, 0.05 mmol of tin (II) acetate, 3.3 mL of oleic acid, 3.3 mL of oleylamine and 30 mL of xylene were put into a reactor, and then stirred for about 30 minutes in a vacuum atmosphere. After the atmosphere was replaced with N₂, the temperature was raised up to 100° C., and the reactor was maintained for about 30 minutes. 1 mL of DI water was rapidly injected into the stabilized mixture, and then the reaction was maintained for about 5 hours. The temperature of the reaction-terminated mixture was cooled to room temperature, and then an excessive amount of ethanol was injected to thereby precipitate synthesized SnO₂. Then, the obtained solid was dispersed into hexane to synthesize a Sn⁴⁺_{0.95}Sn²⁺_{0.05}O_{1.95} seed.

For further growth of Sn⁴⁺_{0.95}Sn²⁺_{0.05}O_{1.95}, 0.95 mmol of tin (IV) acetate, 0.05 mmol of tin (II) acetate, 3.3 mL of oleic acid and 10 mL of trioctylamine were put into the reactor, the temperature was raised to 120° C., and then the mixture was stirred for about 30 minutes in a vacuum atmosphere. The atmosphere was replaced by N₂, then the Sn⁴⁺_{0.95}Sn²⁺_{0.05}O_{1.95} seed was injected, and then the reaction was maintained for about 1 hour. The temperature of the reaction-terminated Sn⁴⁺_{0.95}Sn²⁺_{0.05}O_{1.95} nanoparticle solution was cooled to room temperature, then the solution was purified twice utilizing hexane and ethanol, and then was dispersed into cyclohexybenzene.

### Light-Emitting Element According to Example 3

To synthesize Sn⁴⁺_{0.9}Sn²⁺_{0.1}O_{1.9} nanoparticle, 0.9 mol of tin (IV) acetate, 0.1 mmol of tin (II) acetate, 3.3 mL of oleic acid, 3.3 mL of oleylamine and 30 mL of xylene were put into a reactor, and then stirred for about 30 minutes in a vacuum atmosphere. After the atmosphere was replaced with N₂, the temperature was raised up to 100° C. and the reactor was maintained for about 30 minutes. 1 mL of DI water was rapidly injected into the stabilized mixture, and then the reaction was maintained for about 5 hours. The temperature of the reaction-terminated mixture was cooled to room temperature, and then an excessive amount of ethanol was injected to thereby precipitate synthesized SnO₂. Then, the obtained solid was dispersed into hexane to synthesize a Sn⁴⁺_{0.9}Sn²⁺_{0.1}O_{1.9} seed.

For further growth of Sn⁴⁺_{0.9}Sn²⁺_{0.1}O_{1.9}, 0.9 mmol of tin (IV) acetate, 0.1 mmol of tin (II) acetate, 3.3 mL of oleic acid, and 10 mL of trioctylamine were put into the reactor, the temperature was raised to 120° C., and then the mixture was stirred for about 30 minutes in a vacuum atmosphere. The atmosphere was replaced by N₂, then the Sn⁴⁺_{0.9}Sn²⁺_{0.1}O_{1.9} seed was injected, and then the reaction was maintained for about 1 hour. The temperature of the reaction-terminated Sn⁴⁺_{0.9}Sn²⁺_{0.1}O_{1.9} nanoparticle solution was cooled to room temperature, then the solution was purified twice utilizing hexane and ethanol, and then was dispersed into cyclohexybenzene.

### Light-Emitting Element According to Example 4

To synthesize Sn⁴⁺_{0.9}Sn²⁺_{0.2}O_{1.8} nanoparticle, 0.8 mmol of tin (IV) acetate, 0.2 mmol of tin (II) acetate, 3.3 mL of oleic acid, 3.3 mL of oleylamine, and 30 mL of xylene were put into a reactor, and then stirred for 30 minutes in a vacuum atmosphere. After the atmosphere was replaced with N₂, temperature was raised up to 100° C., and the reactor was maintained for about 30 minutes. 1 mL of DI water was rapidly injected into the stabilized mixture, and then the reaction was maintained for about 5 hours. The temperature of the reaction-terminated mixture was cooled to room temperature, and then an excessive amount of ethanol was injected to thereby precipitate synthesized SnO₂. Then, the obtained solid was dispersed into hexane to synthesize a Sn⁴⁺_{0.8}Sn²⁺_{0.2}O_{1.8} seed.

For further growth of Sn⁴⁺_{0.8}Sn²⁺_{0.2}O_{1.8, 0.8} mmol of tin (IV) acetate, 0.2 mmol of tin (II) acetate, 3.3 mL of oleic acid and 10 mL of trioctylamine were put into the reactor, the temperature was raised to 120° C., and then the mixture was stirred for about 30 minutes in a vacuum atmosphere. The atmosphere was replaced by N₂, then the Sn⁴⁺_{0.8}Sn²⁺_{0.2}O_{1.8} seed was injected, and then the reaction was maintained for about 1 hour. The temperature of the reaction-terminated Sn⁴⁺_{0.8}Sn²⁺_{0.2}O_{1.8} nanoparticle solution was cooled to room temperature, then the solution was purified twice utilizing hexane and ethanol, and then the obtained solid was dispersed into cyclohexybenzene.

### Light-Emitting Element According to Example 5

To synthesize Sn⁴⁺_{0.7}Sn²⁺_{0.3}O_{1.7} nanoparticle, 0.7 mmol of tin (IV) acetate, 0.3 mmol of tin (II) acetate, 3.3 mL of oleic acid, 3.3 mL of oleylamine and 30 mL of xylene were put into a reactor, and then stirred for about 30 minutes in a vacuum atmosphere. After the atmosphere was replaced with N₂, the temperature was raised up to 100° C. and the reactor was maintained for about 30 minutes. 1 mL of DI water was rapidly injected into the stabilized mixture, and then the reaction was maintained for about 5 hours. The temperature of the reaction-terminated mixture was cooled to room temperature, and then an excessive amount of ethanol was injected to thereby precipitate synthesized SnO₂. Then, the obtained solid was dispersed into hexane to synthesize a Sn⁴⁺_{0.7}Sn²⁺_{0.3}O_{1.7} seed.

For further growth of Sn⁴⁺_{0.7}Sn²⁺_{0.3}O_{1.7, 0.7} mmol of tin (IV) acetate, 0.3 mmol of tin (II) acetate, 3.3 mL of oleic acid and 10 mL of trioctylamine were put into the reactor, the temperature was raised to 120° C., and then the mixture was stirred for about 30 minutes in a vacuum atmosphere. The atmosphere was replaced by N₂, then the Sn⁴⁺_{0.7}Sn²⁺_{0.3}O_{1.7} seed was injected, and then the reaction was maintained for about 1 hour. The temperature of the reaction-terminated Sn⁴⁺_{0.7}Sn²⁺_{0.3}O_{1.7} nanoparticle solution was cooled to room temperature, then the solution was purified twice utilizing hexane and ethanol, and then was dispersed in cyclohexybenzene.

Comparative example nanoparticles were formed through following processes.

### Manufacture of Nanoparticle According to Comparative Example 1

To synthesize ZnMgO nanoparticle, 65.2 mmol of zinc acetate dihydrate, 14.8 mmol of magnesium acetate tetrahydrate, and 320 mL of dimethyl sulfoxide were put into a reactor, and then stirred for about 120 minutes. Thereafter, the temperature of the reactor was cooled down to 4° C. and then 80 mL of a mixture solution of 1 M of tetramethylammonium hydroxide pentahydrate (TMAH) and ethanol was injected for about 20 minutes. After the injection of the TMAH solution was completed, the reaction was maintained for about 1 hour and 20 minutes, and then the synthesized ZnMgO was precipitated utilizing acetone and hexane. The finally precipitated nanoparticles were dispersed into ethanol.

### Manufacture of Nanoparticle According to Comparative Example 2

To synthesize a SnO₂ nanoparticle, 1 mmol of tin (IV) acetate, 3.3 mL of oleic acid, 3.3 mL of oleylamine, and 30 mL of xylene were put into a reactor, and then stirred for about 30 minutes in a vacuum atmosphere. The atmosphere was replaced with N₂, then the temperature was raised up to 100° C. and then the reactor was maintained for about 30 minutes. 1 mL of DI water was rapidly injected into the stabilized mixture, and then the reaction was maintained for about 5 hours. The temperature of the reaction-terminated mixture was cooled to room temperature, and then an excessive amount of ethanol was injected to thereby precipitate synthesized SnO₂. Then, the obtained solid was dispersed into hexane to synthesize a SnO₂ seed.

For further growth of SnO₂, 1 mmol of tin (IV) acetate, 3.3 mL of oleic acid, and 10 mL of trioctylamine were put into the reactor, the temperature was raised to 120° C., and then the mixture was stirred for about 30 minutes in a vacuum atmosphere. The atmosphere was replaced by N₂, then the SnO₂ seed was injected, and then the reaction was maintained for about 1 hour. The reaction-terminated SnO₂ nanoparticle solution was cooled to room temperature, then was purified twice utilizing hexane and ethanol, and then was dispersed into cyclohexybenzene.

### Manufacture of Nanoparticle According to Comparative Example 3

To synthesize Sn⁴⁺_{0.6}Sn²⁺_{0.4}O_{1.6} nanoparticle, 0.6 mmol of tin (IV) acetate, 0.4 mmol of tin (II) acetate, 3.3 mL of oleic acid, 3.3 mL of oleylamine, and 30 mL of xylene were put into a reactor, and then stirred for about 30 minutes in a vacuum atmosphere. The atmosphere was replaced with N₂, then the temperature was raised up to 100° C. and then the reactor was maintained for about 30 minutes. 1 mL of DI water was rapidly injected into the stabilized mixture, and then the reaction was maintained for about 5 hours. The temperature of the reaction-terminated mixture was cooled to room temperature, and then an excessive amount of ethanol was injected to thereby precipitate synthesized SnO₂. Then, the obtained solid was dispersed into hexane to synthesize a Sn⁴⁺_{0.6}Sn²⁺_{0.4}O_{1.6} seed.

For further growth of Sn⁴⁺_{0.6}Sn²⁺_{0.4}O_{1.6, 0.6} mmol of tin (IV) acetate, 0.4 mmol of tin (II) acetate, 3.3 mL of oleic acid, and 10 mL of trioctylamine were put into the reactor, the temperature was raised to 120° C., and then the mixture was stirred for about 30 minutes in a vacuum atmosphere. The atmosphere was replaced by N₂, then the Sn⁴⁺_{0.6}Sn²⁺_{0.4}O_{1.6} seed was injected, and then the reaction was maintained for about 1 hour. The reaction-terminated Sn⁴⁺_{0.6}Sn²⁺_{0.4}O_{1.6} nanoparticle solution was cooled to room temperature, then was purified twice utilizing hexane and ethanol, and then was dispersed in cyclohexybenzene.

### Manufacture of Light-Emitting Element According to Example 1

ITO glass substrate (50×50 mm, 15 Ω/cm²), which is a glass substrate for EL-QD (a product of Samsung-Corning Co), was ultrasonically cleaned utilizing distilled water and isopropyl alcohol sequentially, and then UV ozone cleansing was performed for about 30 minutes. After cleansing, PEDOT:PSS (Clevios™ HIL8) was spin-coated on the glass substrate, on which a transparent electrode line is formed, to form a film having a thickness of about 60 nm, and then the glass was baked at about 120° C. for about 10 minutes to form a hole injection layer. Compound 101 was spin-coated on the hole injection layer to form a film having a thickness of about 20 nm, and then the glass was baked at about 120° C. for about 10 minutes to form a hole transport layer. Green InP QD dispersed into octane was spin-coated on the hole transport layer to form a film having a thickness of about 20 nm, and then the glass was baked at about 100° C. for about 10 minutes to form a green emission layer. An inorganic nanoparticle solution was spin-coated on the green emission layer to form a film having a thickness of about 30 nm, and then the glass was baked at about 120° C. for about 10 minutes to form an electron transport layer. The glass substrate was mounted on a substrate holder of a vacuum deposition equipment, and then Al was deposited on the electron transport layer to form an anode having a thickness of about 100 nm, thereby manufacturing a quantum dot light-emitting element. As the equipment utilized in deposition, Sunicel plus 200 deposition equipment made by Sunic System Co., Ltd. was utilized.

### Materials Utilized in Manufacturing of Light-Emitting Element

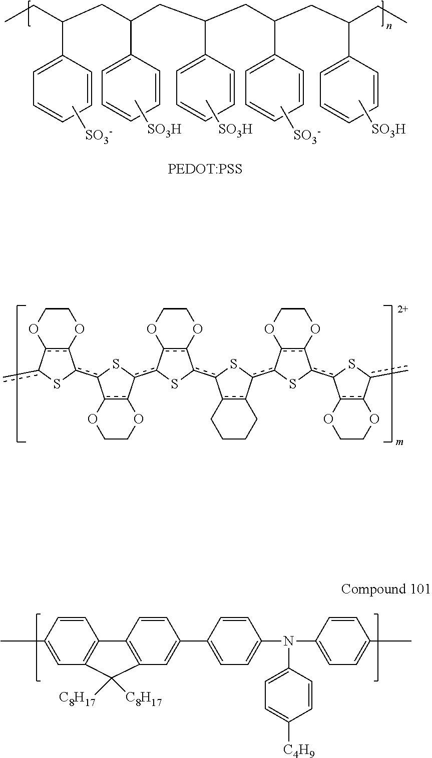

### Manufacture of Light-Emitting Element According to Example 2

A light-emitting element according to Example 2 was manufactured in substantially the same manner as the light-emitting element according to Example 1, except that the material included in the electron transport region is a nanoparticle according to Example 2.

### Manufacture of Light-Emitting Element According to Example 3

A light-emitting element according to Example 3 was manufactured in substantially the same manner as the light-emitting element according to Example 1, except that the material included in the electron transport region is a nanoparticle according to Example 3.

### Manufacture of Light-Emitting Element According to Example 4

A light-emitting element according to Example 4 was manufactured in substantially the same manner as the light-emitting element according to Example 1, except that the material included in the electron transport region is a nanoparticle according to Example 4.

### Manufacture of Light-Emitting Element According to Example 5)

A light-emitting element according to Example 5 was manufactured in substantially the same manner as the light-emitting element according to Example 1, except that the material included in the electron transport region is a nanoparticle according to Example 5.

### (Manufacture of Light-Emitting Element According to Comparative Example 1)

A light-emitting element according to Comparative Example 1 was manufactured in substantially the same manner as the light-emitting element according to Example 1, except that the material included in the electron transport region is a nanoparticle according to Comparative Example 1.

### (Manufacture of Light-Emitting Element According to Comparative Example 2)

A light-emitting element according to Comparative Example 2 was manufactured in substantially the same manner as the light-emitting element according to Example 1, except that the material included in the electron transport region is a nanoparticle according to Comparative Example 2.

### (Manufacture of Light-Emitting Element According to Comparative Example 3)

A light-emitting element according to Comparative Example 3 was manufactured in substantially the same manner as the light-emitting element according to Example 1, except that the material included in the electron transport region is a nanoparticle according to Comparative Example 3.

### (2) Evaluation of Physical Properties of Nanoparticles and Characteristics of Light-Emitting Elements

### (Evaluation of Physical Properties of Nanoparticles)

PL QY defect emission (%), Rel. PL decreases ratios, organic material contents on a surface, and changes of a DLS average particle size (e.g., an average particle size (e.g., diameter) measured utilizing dynamic light scattering) (nm) of the above-described nanoparticles according to Examples and Comparative Examples were evaluated and the evaluation results were listed in Table 1. For PL QY defect emission (%), absolute quantum yield (PL QY) of photoluminescence defect emission from surface defects of metal nanoparticles in liquid state was measured in the visible light region utilizing the QE-2100 measurement system made by Otsuka Electronics Co., Ltd. A green InP dispersed into octane as a solvent was applied onto the glass utilizing a spin coating method to a thickness of about 400 Å, then was heated at about 140° C. for about 10 minutes to dry off the solvent, thereby forming an emission layer, and emission intensity was measured utilizing the FluoroMax Plus equipment. Then, a metal nanoparticle solution was spin coated in substantially the same manner as above to form a layer having a thickness of about 400 Å, and then emission intensity was measured utilizing the FluoroMax Plus equipment to thereby calculate a decline in luminous efficiency with respect to the initial value. The organic material content (e.g., amount) on a surface was measured utilizing a thermogravimetric analysis, and, after drying the inorganic nanoparticles, was measured utilizing the TGA5500 equipment made by TA Instrument. Ink compositions containing nanoparticles according to each Example and Comparative Example were left at room temperature, and then particle sizes thereof were measured after 21 days. The particle sizes were measured utilizing the DLS measurement system (Nano-ZS90 made by Malvern Panalytical.).

A greater PL QY defect emission (%) value indicates that there are more surface defects. Smaller absolute values of PL QY defect emission (%) and Rel, PL decrease ratio indicate that decreases in emission due to defects are less, and thus luminous efficiency is excellent or suitable. The organic material content (e.g., amount) on a surface is an indicator exhibiting a degree of a content (e.g., amount) of organic materials contained in the nanoparticle. A higher organic material content (e.g., amount) on a surface indicates that more organic materials are contained in the nanoparticle. It is understood that more ligands, which are organic materials, are contained, stability of materials are excellent or suitable. DLS average particle size is an indicator indicating an average size (e.g., diameter) of the nanoparticles, changes in nanoparticle size between a value measured on Od (i.e., day 0), which is a first measurement date, and a value measured on 21d (i.e., day 21), which is 21 days after from Od, were observed (e.g., calculated), and if (e.g., when) the difference in size (e.g., size changes) is great, it is understood as that jetting characteristics of the ink have deteriorated, which is caused by aggregation of the nanoparticles.

TABLE 1

| | PL QY | | Organic | | |
|---|---|---|---|---|---|
| | defect | Rel. PL | material | DLS Average | |
| | emission | decrease | content on | particle size (nm) | |
| | (%) | ratio | surface | 0 d | 21 d |
| Example 1 | 2 | −7 | 18.8 | 10.0 | 10.1 |
| Nanoparticle | | | | | |
| Example 2 | 2 | −6 | 18.9 | 11.1 | 11.0 |
| Nanoparticle | | | | | |
| Example 3 | 2 | −7 | 19.0 | 10.2 | 10.4 |
| Nanoparticle | | | | | |
| Example 4 | 2 | −7 | 18.8 | 10.1 | 10.5 |
| Nanoparticle | | | | | |
| Example 5 | 2 | −8 | 18.4 | 10.2 | 10.4 |
| Nanoparticle | | | | | |
| Comparative | 58 | −22 | 16.8 | 13.3 | 300 |
| Example 1 | | | | | |
| Nanoparticle | | | | | |
| Comparative | 3 | −9 | 19.0 | 10.2 | 10.4 |
| Example 2 | | | | | |
| Nanoparticle | | | | | |
| Comparative | 2 | −7 | 18.8 | 10.1 | 10.3 |
| Example 3 | | | | | |
| Nanoparticle | | | | | |

Referring to Table 1, it is shown that the nanoparticles according to Example 1 to Example 5 have relatively lower absolute values of PL QY defect emission (%) and Rel. PL decrease ratio than the nanoparticles according to Comparative Example 1 and Comparative Example 2, and thus a decrease in emission due to defects is less, thereby having excellent or suitable luminous efficiency. It is shown that each of the nanoparticles according to Example 1 to Example 5 has a higher organic material content (e.g., amount) on a surface than the nanoparticle according to Comparative Example 1, thus more organic materials are included on the surface, and because the core of the nanoparticle is protected by more ligands and an average distance between nanoparticles is greater, aggregation between nanoparticles is improved or reduced, and jetting characteristics of the ink is excellent or suitable. It is understood that, because the changes in the average particle size of the nanoparticles according to Example 1 to Example 5 are small or not significantly, a reverse-reaction caused by oxygen, moisture, and/or the like, or the aggregation phenomenon between the nanoparticles are improved, and thus jetting characteristics of the ink are excellent or suitable.

### Evaluation of Characteristics of Light-Emitting Element

A driving voltage (V), element efficiency (Cd/A), and an element lifespan (@T₉₀, h) of the above-described light-emitting elements according to Examples and Comparative Examples were evaluated. The evaluation results of the light-emitting elements according to Example 1 to Example 5, and Comparative Example 1 to Comparative Example 3 were listed in Table 1. To evaluate characteristics of the light-emitting elements manufactured according to Example 1 to Example 5, and Comparative Example 1 to Comparative Example 3, the driving voltage (V) and the luminous efficiency (Cd/A) at luminance of 1280 cd/m² were measured respectively utilizing Keithley SMU 236 and the luminance meter PR650, and the absolute time taken for luminance to decrease to 90% of the initial luminance was measured as a lifespan (@T₉₀, h).

TABLE 2

| | Efficiency | Driving voltage | Lifespan |
|---|---|---|---|
| | (Cd/A) | (V) | (@T₉₀, h) |
| Example 1 | 74.0 | 6.2 | 180 |
| Example 2 | 120.4 | 6.4 | 213 |
| Example 3 | 118.2 | 6.5 | 218 |
| Example 4 | 90.0 | 7.0 | 190 |
| Example 5 | 65.2 | 7.3 | 101 |
| Comparative | 62.2 | 5.2 | 14 |
| Example 1 | | | |
| Comparative | 55.2 | 4.6 | 18 |
| Example 2 | | | |
| Comparative | 30.1 | 8.2 | 15 |
| Example 3 | | | |

Referring to the results in Table 2, it can be seen that the light-emitting elements according to Examples, each utilizing the nanoparticles according to one or more embodiments of the present disclosure as materials for the electron transport layer, have relatively higher luminous efficiency and longer lifespan than the light-emitting elements according to Comparative Examples. For example, in Formula 1, if x is greater than about 0.3 (Comparative Example 3), the light-emitting element is observed to have a significant (e.g., rapid) decrease in efficiency and lifespan.

In the nanoparticles included in the light-emitting elements according to Examples, Sn forming a divalent cation has relatively lower electron transport and injection rates than Sn forming a tetravalent cation, and thus if (e.g., when) the ratio of Sn forming a divalent cation increases, the electron transport and injection rates in the light-emitting element may be controlled. In the nanoparticles according to Example 1 to Example 5, because the ratio of Sn forming a tetravalent cation to Sn forming a divalent cation is adjusted from 98:2 to 70:30, thus the difference between the electron transport rate and the hole transport rate decreases, thus charge imbalance in the emission layer is improved, and thus luminous efficiency and lifespan of the light-emitting elements are improved.

Also, as shown in Table 1, the nanoparticle according to Comparative Example 3 has similar levels of absolute values of PL QY defect emission (%) and Rel. PL decrease ratio to the nanoparticles according to Examples. However, it can be confirmed that, in the nanoparticle according to Comparative Example 3, the ratio of Sn forming a tetravalent cation to Sn forming a divalent cation is out of the above-described range of about 98:2 to about 70:30, and thus if (e.g., when) the nanoparticle according to Comparative Example 3 is utilized in the light-emitting element, the light-emitting element has decreased efficiency and lifespan. Similar to the nanoparticle according to Comparative Example 3, if (e.g., when) the ratio of Sn forming a divalent cation becomes excessively (or substantially) high, exceeding the range according to the present disclosure, the electron transport rate is relatively lowered than the hole transport rate, and thus charge imbalance in the emission layer occurs. Therefore, if (e.g., when) the nanoparticle according to Comparative Example 3 is applied in the element, efficiency and lifespan of the light-emitting element decreases.

The light-emitting element according to one or more embodiments may have improved element characteristics of high efficiency and a long lifespan.

The ink composition according to one or more embodiments may contribute to improvements in high efficiency and long lifespan of the light-emitting element.

The display device according to one or more embodiments may include the light-emitting element having excellent or suitable efficiency and lifespan.

In the context of the present application and unless otherwise defined, the terms “use,” “using,” and “used” may be considered synonymous with the terms “utilize,” “utilizing,” and “utilized,” respectively.

Throughout the disclosure, the expression “at least one of a, b or c”, “at least one selected from a, b, and c”, “at least one selected from the group consisting of a, b, and c”, “at least one from among a, b, and c”, etc., indicates only a, only b, only c, both (e.g., simultaneously) a and b, both (e.g., simultaneously) a and c, both (e.g., simultaneously) b and c, all of a, b, and c, or variations thereof.

The use of “may” when describing embodiments of the present disclosure refers to “one or more embodiments of the present disclosure”.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

In addition, the average particle diameter may be measured by a suitable method, for example, may be measured by a particle size analyzer, or may be measured by a transmission electron microscopic image or a scanning electron microscopic image. It is also possible to obtain an average particle diameter value by measuring utilizing a dynamic light scattering method, performing data analysis, counting the number of particles for each particle size range, and calculating from this. Unless otherwise defined, the average particle diameter may refer to the diameter (D₅₀) of particles having a cumulative volume of 50 volume % in the particle size distribution. Also, unless otherwise defined, in the present disclosure, the term “particle diameter” refers to an average diameter when particles are spherical and refers to an average major axis length when particles are non-spherical.

The display device, and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the embodiments of the present disclosure have been described, it is understood that the present disclosure should not be limited to these embodiments, but one or more suitable changes and modifications can be made by one ordinary skilled in the art within the spirit and scope of the present disclosure as hereinafter claimed and equivalents thereof.

What is claimed is:

1. A light-emitting element comprising:
a first electrode;
a functional layer on the first electrode; and
a second electrode on the functional layer,
wherein:
the functional layer comprises a nanoparticle;
the nanoparticle comprises a core and a ligand; and
the core comprises at least one of a first core compound represented by Formula 1, a second core compound represented by Formula 2, or a third core compound represented by Formula 3:
Sn⁴⁺₁₋ₓSn²⁺ₓO₂₋ₓ, Formula 1
where in Formula 1,
x is greater than 0, and less than or equal to about 0.3,
Sn⁴⁺_{1-y}Cu⁺_{2y}O_{2-y}, Formula 2
where in Formula 2,
y is greater than 0, and less than or equal to about 0.3,
Sn⁴⁺_{1-z}Ni²⁺_{z}O_{2-z}, Formula 3
where in Formula 3,
z is greater than 0, and less than or equal to about 0.3.

2. The light-emitting element of claim 1, wherein:
the nanoparticle is composed of the core and the ligand; and
the core is composed of the first core compound.

3. The light-emitting element of claim 2, wherein the nanoparticle has a peak intensity ratio of Sn²⁺ 3d_{5/2} with respect to Sn⁴⁺ 3d_{5/2} of greater than 0, and less than or equal to about 0.6, as measured utilizing X-ray photoelectron spectroscopy.

4. The light-emitting element of claim 2, wherein an absolute quantum yield of the nanoparticle is greater than 0%, and less than or equal to about 5%.

5. The light-emitting element of claim 1, wherein:
the nanoparticle is composed of the core and the ligand; and
the core is composed of at least one of the first core compound, the second core compound, or the third core compound.

6. The light-emitting element of claim 1, wherein the ligand comprises oleic acid, or oleylamine.

7. The light-emitting element of claim 1, wherein the ligand is chemically bonded to the core.

8. The light-emitting element of claim 1, wherein the nanoparticle is doped with a metal atom.

9. The light-emitting element of claim 8, wherein the metal atom comprises at least one of Zn, Mg, Li, or Na.

10. The light-emitting element of claim 1, wherein the functional layer comprises:
a hole transport region on the first electrode;
an emission layer on the hole transport region; and
an electron transport region between the emission layer and the second electrode, and
the electron transport region comprises the nanoparticle.

11. The light-emitting element of claim 10, wherein:
the electron transport region comprises an electron transport layer on the emission layer, and an electron injection layer on the electron transport layer; and
at least one of the electron transport layer or the electron injection layer comprises the nanoparticle.

12. The light-emitting element of claim 10, wherein the emission layer comprises a quantum dot.

13. An ink composition comprising:
a nanoparticle; and
a solvent,
wherein:
the nanoparticle comprises a core and a ligand; and
the core comprises at least one of a first core compound represented by Formula 1, a second core compound represented by Formula 2, or a third core compound represented by Formula 3:
Sn⁴⁺₁₋ₓSn²⁺ₓO₂₋ₓ, Formula 1
where in Formula 1,
x is greater than 0, and less than or equal to about 0.3,
Sn⁴⁺_{1-y}Cu⁺_{2y}O_{2-y}, Formula 2
where in Formula 2,
y is greater than 0, and less than or equal to about 0.3,
Sn⁴⁺_{1-z}Ni²⁺_{z}O_{2-z}, Formula 3
where in Formula 3,
z is greater than 0, and less than or equal to about 0.3.

14. The ink composition of claim 13, wherein the solvent is hydrophobic.

15. The ink composition of claim 13, wherein:
the nanoparticle is composed of the core and the ligand; and
the core is composed of the first core compound.

16. The ink composition of claim 13, wherein:
the nanoparticle is composed of the core and the ligand; and
the core is composed of the second core compound or the third core compound.

17. A display device comprising:
a base layer;
a circuit layer on the base layer; and
a display element layer on the circuit layer and comprising a light-emitting element,
wherein:
the light-emitting element comprises a first electrode, a second electrode on the first electrode, and an electron transport region between the first electrode and the second electrode and comprising a nanoparticle;
the nanoparticle comprises a core and a ligand; and
the core comprises at least one of a first core compound represented by Formula 1, a second core compound represented by Formula 2, or a third core compound represented by Formula 3:
Sn⁴⁺₁₋ₓSn²⁺ₓO₂₋ₓ, Formula 1
where in Formula 1,
x is greater than 0, and less than or equal to about 0.3,
Sn⁴⁺_{1-y}Cu⁺_{2y}O_{2-y}, Formula 2
where in Formula 2,
y is greater than 0, and less than or equal to about 0.3,
Sn⁴⁺_{1-z}Ni²⁺_{z}O_{2-z}, Formula 3
where in Formula 3,
z is greater than 0, and less than or equal to about 0.3.

18. The display device of claim 17, wherein the light-emitting element further comprises a hole transport region on the first electrode, and an emission layer between the hole transport region and the electron transport region.

19. The display device of claim 18, wherein the emission layer comprises a quantum dot.

20. The display device of claim 18, wherein:
the electron transport region comprises an electron transport layer on the emission layer, and an electron injection layer on the electron transport layer, and
at least one of the electron transport layer or the electron injection layer comprises the nanoparticle.
